(19) United States
(12) Patent Application Publication
(10) Pub. No.: US 2024/0186391 A1
(43) Pub. Date: Jun. 6, 2024

(54) GATE-ALL-AROUND DEVICE WITHOUT DIELECTRIC INNER SPACER

(71) Applicant: International Business Machines Corporation, Armonk, NY (US)

(72) Inventors: Julien Frougier, Albany, NY (US); Sung Dae Suk, Watervliet, NY (US); Ruilong Xie, Niskayuna, NY (US); Christopher J. Waskiewicz, Rexford, NY (US); Veeraraghavan S. Basker, Fremont, CA (US)

(21) Appl. No.: 18/062,034

(22) Filed: Dec. 6, 2022

(51) Int. Cl. H01L 29/423; H01L 29/06; H01L 29/08; H01L 29/417; H01L 29/66; H01L 29/775; H01L 29/786

(52) U.S. Cl. CPC H01L 29/42392; H01L 29/0673; H01L 29/0847; H01L 29/41733; H01L 29/66553; H01L 29/6656; H01L 29/775; H01L 29/78696

(57) ABSTRACT

A semiconductor structure includes a first gate-all-around device disposed on a first region of a substrate and a second gate-all-around device disposed on a second region of the substrate. The first gate-all-around device includes a first metal gate stack surrounding a first channel layer. The first metal gate stack is separated from a first source/drain region by a dielectric inner spacer disposed on opposite sides of the first metal gate stack. The second gate-all-around device includes a second metal gate stack surrounding a second channel layer. The second metal gate stack is separated from a second source/drain region by an epitaxial layer disposed on opposite sides of the second metal gate stack.

### BACKGROUND

The present invention generally relates to the field of complementary metal-oxide semiconductor (CMOS) devices, and more particularly to gate-all-around field effect transistor devices.

In contemporary semiconductor device fabrication processes a large number of semiconductor devices, such as field effect transistors (FETs), are fabricated on a single wafer. Some non-planar device architectures, including nanosheet FETs, provide increased device density and increased performance over planar devices. In nanosheet FETs, in contrast to conventional FETs, the gate stack wraps around the full perimeter of each nanosheet, enabling fuller depletion in the channel region, and reducing short-channel effects. The wrap-around gate structures used in nanosheet devices also enable greater management of leakage current in the active regions, even as drive currents increase.

Nanosheet FETs often include thin alternating layers (nanosheets) of different semiconductor materials arranged in a stack. Typically, nanosheets are patterned into nanosheet fins. Once the nanosheet fins are patterned, a gate stack is formed over a channel region of the nanosheet fins, and source/drain regions are formed adjacent to the gate stack. In some devices, once the gate stack or the source/drain regions have been formed, an etching process is performed to selectively remove sacrificial nanosheet layers of one of the dissimilar materials from the fins. The etching process results in the undercutting and suspension of the layers of the nanosheet fin (i.e., nanosheet channel layers) to form nanosheets or nanowires that can be used to form gate-all-around (GAA) devices.

### SUMMARY

According to an embodiment of the present disclosure, a semiconductor structure includes a first gate-all-around device disposed on a first region of a substrate, the first gate-all-around device including a first metal gate stack surrounding a first channel layer, the first metal gate stack being separated from a first source/drain region by a dielectric inner spacer disposed on opposite sides of the first metal gate stack, and a second gate-all-around device disposed on a second region of the substrate, the second gate-all-around device including a second metal gate stack surrounding a second channel layer, the second metal gate stack being separated from a second source/drain region by an epitaxial layer disposed on opposite sides of the second metal gate stack.

According to another embodiment of the present disclosure, a semiconductor structure includes a plurality of channel layers vertically stacked over a substrate, a metal gate stack including a gate dielectric material, the metal gate stack being located between the plurality of channel layers, an epitaxial layer disposed on opposite sides of the metal gate stack, a source/drain region adjacent to the plurality of channel layers and the epitaxial layer, and a diffusion region located at an interface between the source/drain region, the plurality of channel layers and the epitaxial layer, the diffusion region having a U-shaped perimeter that surrounds the source/drain region, the diffusion region including diffused dopant atoms from the source/drain region.

### BRIEF DESCRIPTION OF THE DRAWINGS

The following detailed description, given by way of example and not intended to limit the invention solely thereto, will best be appreciated in conjunction with the accompanying drawings, in which:

FIG. 1 is a top-down view of a semiconductor structure at an intermediate step during a semiconductor manufacturing process depicting different cross-sectional views, according to an embodiment of the present disclosure;

FIG. 2A is a cross-sectional view of the semiconductor structure taken along line X-X, as depicted in FIG. 1, depicting forming a nanosheet stack, according to an embodiment of the present disclosure;

FIG. 2B is a cross-sectional view of the semiconductor structure taken along line Y-Y, as depicted in FIG. 1;

FIG. 3A is a cross-sectional view of the semiconductor structure taken along line X-X, as depicted in FIG. 1, depicting forming a dummy gate, a sacrificial hardmask and sidewall gate spacer, according to an embodiment of the present disclosure;

FIG. 3B is a cross-sectional view of the semiconductor structure taken along line Y-Y, as depicted in FIG. 1;

FIG. 4A is a cross-sectional view of the semiconductor structure taken along line X-X, as depicted in FIG. 1, depicting recessing a nanosheet fin and selectively etching sacrificial semiconductor layers, according to an embodiment of the present disclosure;

FIG. 4B is a cross-sectional view of the semiconductor structure taken along line Y-Y, as depicted in FIG. 1;

FIG. 5A is a cross-sectional view of the semiconductor structure taken along line X-X, as depicted in FIG. 1, depicting forming a first epitaxial layer, according to an embodiment of the present disclosure;

FIG. 5B is a cross-sectional view of the semiconductor structure taken along line Y-Y, as depicted in FIG. 1;

FIG. 6A is a cross-sectional view of the semiconductor structure taken along line X-X, as depicted in FIG. 1, depicting forming source/drain regions, according to an embodiment of the present disclosure;

FIG. 6B is a cross-sectional view of the semiconductor structure taken along line Y-Y, as depicted in FIG. 1;

FIG. 7A is a cross-sectional view of the semiconductor structure taken along line X-X, as depicted in FIG. 1, depicting forming a first dielectric layer and conducting a planarization process, according to an embodiment of the present disclosure;

FIG. 7B is a cross-sectional view of the semiconductor structure taken along line Y-Y, as depicted in FIG. 1;

FIG. 8A is a cross-sectional view of the semiconductor structure taken along line X-X, as depicted in FIG. 1, depicting removing the dummy gate and sacrificial semiconductor layers, according to an embodiment of the present disclosure;

FIG. 8B is a cross-sectional view of the semiconductor structure taken along line Y-Y, as depicted in FIG. 1;

FIG. 9A is a cross-sectional view of the semiconductor structure taken along line X-X, as depicted in FIG. 1, depicting forming a replacement metal gate structure, according to an embodiment of the present disclosure;

FIG. 9B is a cross-sectional view of the semiconductor structure taken along line Y-Y, as depicted in FIG. 1;

FIG. 10A is a cross-sectional view of the semiconductor structure taken along line X-X, as depicted in FIG. 1, depicting contact metallization, according to an embodiment of the present disclosure;

FIG. 10B is a cross-sectional view of the semiconductor structure taken along line Y-Y, as depicted in FIG. 1;

FIG. 11A is a cross-sectional view of the semiconductor structure taken along line X-X, as depicted in FIG. 1, depicting recessing the nanosheet fin, selectively etching the sacrificial semiconductor layers, growing the first epitaxial layer, and trimming the first epitaxial layer, according to an alternate embodiment of the present disclosure;

FIG. 11B is a cross-sectional view of the semiconductor structure taken along line Y-Y, as depicted in FIG. 1;

FIG. 12A is a cross-sectional view of the semiconductor structure taken along line X-X, as depicted in FIG. 1, depicting forming the source/drain regions, according to an alternate embodiment of the present disclosure;

FIG. 12B is a cross-sectional view of the semiconductor structure taken along line Y-Y, as depicted in FIG. 1;

FIG. 13A is a cross-sectional view of the semiconductor structure taken along line X-X, as depicted in FIG. 1, depicting forming the first dielectric layer and conducting a planarization process, according to an alternate embodiment of the present disclosure;

FIG. 13B is a cross-sectional view of the semiconductor structure taken along line Y-Y, as depicted in FIG. 1;

FIG. 14A is a cross-sectional view of the semiconductor structure taken along line X-X, as depicted in FIG. 1, depicting removing the dummy gate and sacrificial semiconductor layers, according to an alternate embodiment of the present disclosure;

FIG. 14B is a cross-sectional view of the semiconductor structure taken along line Y-Y, as depicted in FIG. 1;

FIG. 15A is a cross-sectional view of the semiconductor structure taken along line X-X, as depicted in FIG. 1, depicting forming the replacement metal gate structure, according to an alternate embodiment of the present disclosure;

FIG. 15B is a cross-sectional view of the semiconductor structure taken along line Y-Y, as depicted in FIG. 1;

FIG. 16A is a cross-sectional view of the semiconductor structure taken along line X-X, as depicted in FIG. 1, depicting forming metal contacts, according to an alternate embodiment of the present disclosure;

FIG. 16B is a cross-sectional view of the semiconductor structure taken along line Y-Y, as depicted in FIG. 1;

FIG. 17A is a cross-sectional view of the semiconductor structure taken along line X-X, as depicted in FIG. 1, depicting forming the nanosheet stack, patterning the nanosheet fin, and forming shallow trench isolation regions, according to an alternate embodiment of the present disclosure;

FIG. 17B is a cross-sectional view of the semiconductor structure taken along line Y-Y, as depicted in FIG. 1;

FIG. 18A is a cross-sectional view of the semiconductor structure taken along line X-X, as depicted in FIG. 1, depicting forming the dummy gate, sidewall gate spacer, recessing the nanosheet fin, selectively etching sacrificial semiconductor layer, forming the first epitaxial layer, forming source/drain regions, forming the first dielectric layer and conducting a planarization process, according to an alternate embodiment of the present disclosure;

FIG. 18B is a cross-sectional view of the semiconductor structure taken along line Y-Y, as depicted in FIG. 1;

FIG. 19A is a cross-sectional view of the semiconductor structure taken along line X-X, as depicted in FIG. 1, depicting removing the dummy gate and sacrificial semiconductor layers, according to an alternate embodiment of the present disclosure;

FIG. 19B is a cross-sectional view of the semiconductor structure taken along line Y-Y, as depicted in FIG. 1;

FIG. 20A is a cross-sectional view of the semiconductor structure taken along line X-X, as depicted in FIG. 1, depicting etching the semiconductor channel layers, according to an alternate embodiment of the present disclosure;

FIG. 20B is a cross-sectional view of the semiconductor structure taken along line Y-Y, as depicted in FIG. 1;

FIG. 21A is a cross-sectional view of the semiconductor structure taken along line X-X, as depicted in FIG. 1, depicting forming the replacement metal gate structure, according to an alternate embodiment of the present disclosure;

FIG. 21B is a cross-sectional view of the semiconductor structure taken along line Y-Y, as depicted in FIG. 1;

FIG. 22A is a cross-sectional view of the semiconductor structure taken along line X-X, as depicted in FIG. 1, depicting forming metal contacts, according to an alternate embodiment of the present disclosure; and

FIG. 22B is a cross-sectional view of the semiconductor structure taken along line Y-Y, as depicted in FIG. 1.

The drawings are not necessarily to scale. The drawings are merely schematic representations, not intended to portray specific parameters of the invention. The drawings are intended to depict only typical embodiments of the invention. In the drawings, like numbering represents like elements.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

It is understood that although the disclosed embodiments include a detailed description of an exemplary nanosheet FET architecture having silicon and silicon germanium nanosheets, implementation of the teachings recited herein are not limited to the particular FET architecture described herein. Rather, embodiments of the present invention are capable of being implemented in conjunction with any other type of FET device now known or later developed.

Embodiments of the present disclosure provide a semiconductor structure, and a method of making the same, in which sacrificial layers in a nanosheet stack are selectively indented to define a nominal gate length (L_{g}) and create inner spacer cavities that are subsequently pinched-off by a doped silicon-based buffer epitaxy layer for separating the gate region from the source/drain regions, thereby eliminating the typical step of forming a dielectric inner spacer. In one or more embodiments, the source/drain regions are in contact with the doped silicon-based buffer epitaxy layer and edges of the silicon channel layers in the nanosheet stack. The described embodiments may, among other benefits, reduced process disruption compared to current process-of-record integration schemes, enable targeted L_{g} without dielectric inner spacer, eliminate the risk of epi etch-out through inner spacer breach, improve p-FET SiGe source-drain epitaxy nucleation on bottom dielectric isolation (BDI)/Silicon-on-Insulator (SOI) structures, and enable p-FET strain by providing a bottom-up epi growth component when the substrate is exposed in the source-drain regions.

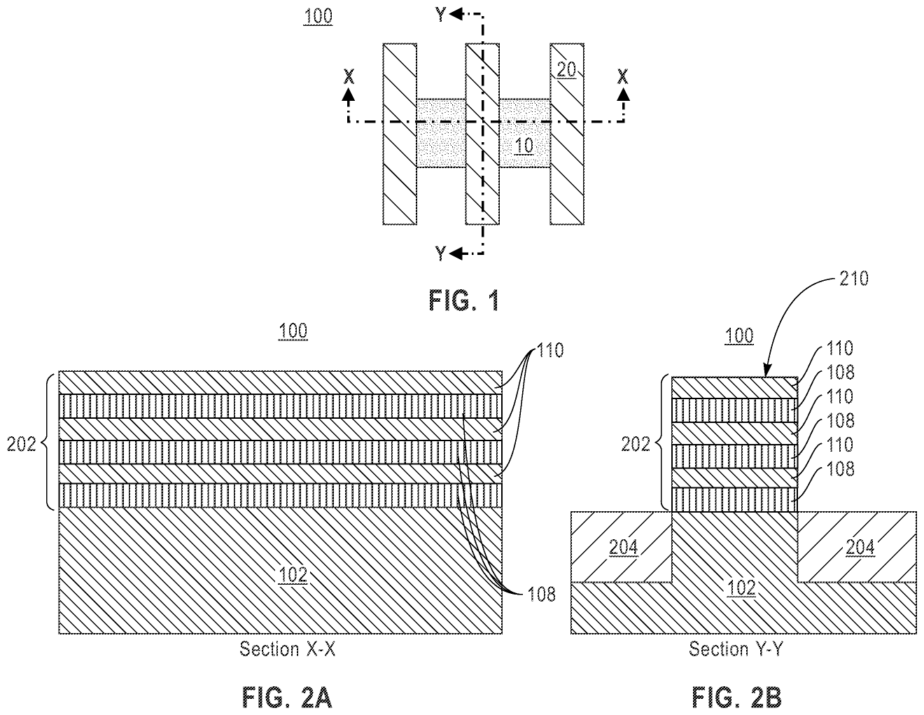

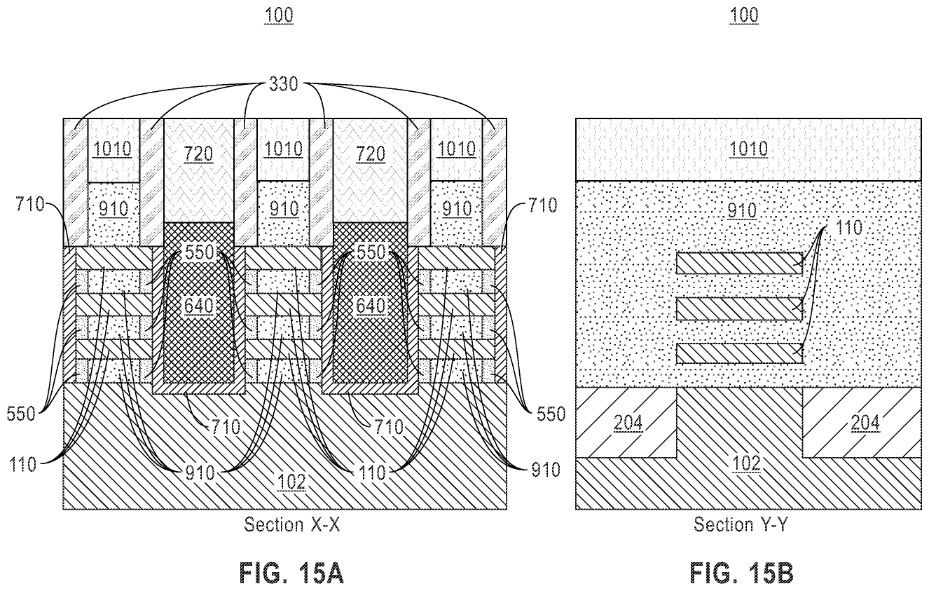

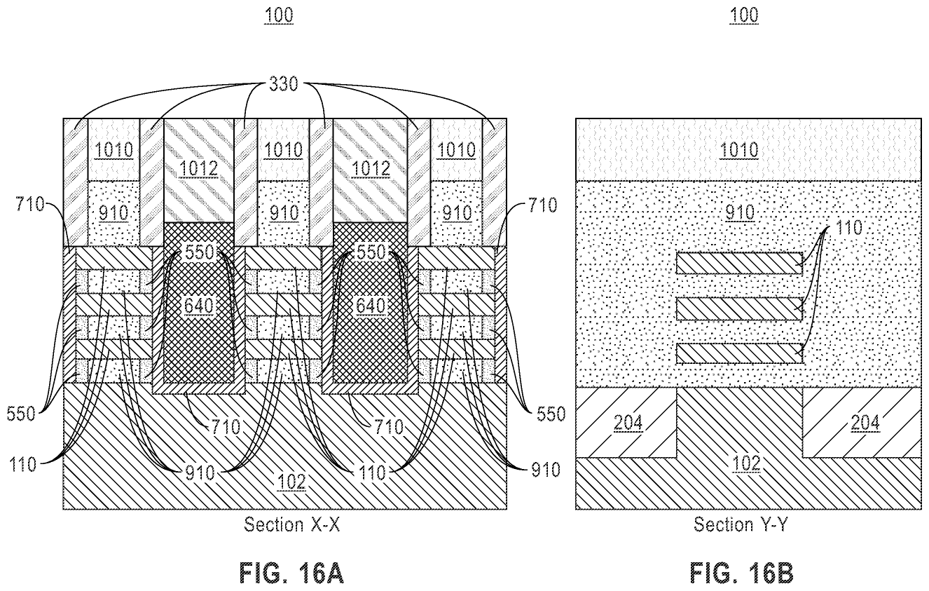

Embodiments by which the doped silicon-based buffer epitaxy layer can be formed are described in detailed below by referring to the accompanying drawings in FIGS. 1-22B.

Referring now to FIG. 1, a top-down view of a semiconductor structure 100 is shown at an intermediate step during a semiconductor manufacturing process, according to an embodiment of the present disclosure. Particularly, FIG. 1 depicts different cross-sectional views of the semiconductor structure 100 that will be used to describe embodiments of the present disclosure. The cross-sectional views are taken along line X-X and line Y-Y. As depicted in the figure, line X-X represents a cut along a nanosheet fin structure or nanosheet fin region 10 of the semiconductor structure 100, while line Y-Y represents a cut along a gate structure or gate region 20 of the semiconductor structure 100.

For ease of illustration and description of the present embodiments, all subsequent figures accompanied by the letter A are cross-sections taken along line X-X (nanosheet fin region 10), and all subsequent figures accompanied by the letter B are cross-sections taken along line Y-Y (gate region 20).

Referring now to FIGS. 2A-2B, cross-sectional views of the semiconductor structure 100 are shown after forming a nanosheet stack 202 above a semiconductor substrate 102, according to an embodiment of the present disclosure. In this embodiment, FIG. 2A is a cross-sectional view of the semiconductor structure 100 taken along line X-X, as depicted in FIG. 1, and FIG. 2B is a cross-sectional view of the semiconductor structure 100 taken along line Y-Y, as depicted in FIG. 1.

An alternating sequence of layers of sacrificial semiconductor material and layers of semiconductor channel material vertically stacked one on top of another in a direction perpendicular to the semiconductor substrate 102 forms the nanosheet stack 202, as illustrated in the figures. Specifically, the alternating sequence includes a sacrificial semiconductor layer 108 above the semiconductor substrate 102, and a semiconductor channel layer 110 above the sacrificial semiconductor layer 108. In the example depicted in the figure, alternating sacrificial semiconductor layers 108 and semiconductor channel layers 110 are formed in a stack above the semiconductor substrate 102. The term sacrificial, as used herein, means a layer or other structure, that is (or a part thereof is) removed before completion of the final device. For instance, in the example being described, portions of the sacrificial semiconductor layers 108 will be removed from the stack in the channel region of the device to permit the semiconductor channel layers 110 to be released from the nanosheet stack 202. It is notable that while in the present example the sacrificial semiconductor layers 108 and the semiconductor channel layers 110 are made of silicon germanium (SiGe) and silicon (Si), respectively, any combination of sacrificial and channel materials may be employed in accordance with the present techniques.

According to an embodiment, the semiconductor substrate 102 may be, for example, a bulk substrate, which may be made from any of several known semiconductor materials such as, for example, silicon, germanium, silicon-germanium alloy, and compound (e.g. III-V and II-VI) semiconductor materials. Non-limiting examples of compound semiconductor materials include gallium arsenide, indium arsenide, and indium phosphide, or indium gallium phosphide. Typically, the semiconductor substrate 102 may be approximately, but is not limited to, several hundred microns thick. In other embodiments, the semiconductor substrate 102 may be a layered semiconductor such as a silicon-on-insulator or SiGe-on-insulator, where a buried insulator layer, separates a base substrate from a top semiconductor layer.

In general, layers of the nanosheet stack 202 (e.g., SiGe/Si layers) can be formed by epitaxial growth by using the semiconductor substrate 102 as the seed layer. Terms such as “epitaxial growth and/or deposition” and “epitaxially formed and/or grown” refer to the growth of a semiconductor material on a deposition surface of a semiconductor material, in which the semiconductor material being grown has the same or substantially similar crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same or substantially similar crystalline characteristics as the deposition surface on which it is formed. For example, an epitaxial semiconductor material deposited on a {100} crystal surface will take on a {100} orientation. In some embodiments, epitaxial growth and/or deposition processes are selective to forming on a semiconductor surface, and do not deposit material on dielectric surfaces, such as silicon dioxide or silicon nitride surfaces.

Non-limiting examples of various epitaxial growth processes include rapid thermal chemical vapor deposition (RTCVD), low-energy plasma deposition (LEPD), ultra-high vacuum chemical vapor deposition (UHVCVD), atmospheric pressure chemical vapor deposition (APCVD), metalorganic chemical vapor deposition (MOCVD), low-pressure chemical vapor deposition (LPCVD), limited reaction processing CVD (LRPCVD), and molecular beam epitaxy (MBE). The temperature for an epitaxial deposition process can range from 500° C. to 900° C. Although higher temperatures typically results in faster deposition, the faster deposition may result in crystal defects and film cracking.

A number of different precursors may be used for the epitaxial growth of the alternating sequence of SiGe/Si layers in the nanosheet stack 202. In some embodiments, a gas source for the deposition of epitaxial semiconductor material includes a silicon containing gas source, a germanium containing gas source, or a combination thereof. For example, an epitaxial silicon layer may be deposited from a silicon gas source including, but not necessarily limited to, silane, disilane, trisilane, tetrasilane, hexachlorodisilane, tetrachlorosilane, dichlorosilane, trichlorosilane, and combinations thereof. An epitaxial germanium layer can be deposited from a germanium gas source including, but not necessarily limited to, germane, digermane, halogermane, dichlorogermane, trichlorogermane, tetrachlorogermane and combinations thereof. While an epitaxial silicon germanium alloy layer can be formed utilizing a combination of such gas sources. Carrier gases like hydrogen, helium and argon can be used.

According to an embodiment, the sacrificial semiconductor layers 108 are formed by epitaxially growing a layer of SiGe with a germanium concentration varying from approximately 15 atomic percent to approximately 35 atomic percent.

To continue building the nanosheet stack 202, the semiconductor channel layers 110 are formed by epitaxially growing a Si layer. As depicted in the figure, the nanosheet stack 202 is grown by forming (SiGe) sacrificial semiconductor layers 108 and (Si) semiconductor channel layers 110 in an alternating manner onto the semiconductor substrate 102. Accordingly, each of the sacrificial semiconductor layers 108 and the semiconductor channel layers 110 in the nanosheet stack 202 can be formed in the same manner as described above, e.g., using an epitaxial growth process, to a thickness varying from approximately 5 nm to approximately 15 nm, although other thicknesses are within the contemplated scope of the invention.

Thus, each of the layers in the nanosheet stack 202 have nanoscale dimensions, and thus can also be referred to as nanosheets. Further, as highlighted above, the (Si) semiconductor channel layers 110 in the nanosheet stack 202 will be used to form the channel layers of the device. Consequently, the dimensions of the semiconductor channel layers 110 dictate the dimensions of the channel region of the semiconductor structure 100. In some embodiments, the semiconductor channel layers 110 may include nanowires or nano-ellipses.

As mentioned above, the goal is to produce a stack of alternating (sacrificial and channel) SiGe and Si layers on the wafer. The number of layers in the stack can be tailored depending on the particular application. Thus, the configurations depicted and described herein are merely examples meant to illustrate the present techniques. For instance, the present nanosheet stack 202 can contain more or fewer layers than are shown in the figures.

The nanosheet stack 202 can be used to produce a gate-all-around device that includes vertically stacked semiconductor channel material nanosheets for a positive channel Field Effect Transistor (hereinafter “p-FET”) or a negative channel Field Effect Transistor (hereinafter “n-FET”) device.

With continued reference to FIGS. 2A-2B, known processing techniques have been applied to the sequence of (SiGe) sacrificial semiconductor layers 108 and (Si) semiconductor channel layers 110 (i.e., nanosheet stack 202) to form a nanosheet fin 210. For example, a fin hardmask (not shown) is formed over the nanosheet stack 202. The fin hardmask (not shown) can be formed by first depositing a hard mask material (e.g., silicon nitride) onto the nanosheet stack 202 using, for example, chemical vapor deposition (CVD), plasma enhanced CVD (PECVD) or any suitable technique for dielectric deposition. A photolithographic patterning is conducted on the deposited hardmask material to form a plurality of individual fin hardmasks.

The patterning of the fin hardmask (not shown) is commensurate with a desired footprint and location of the semiconductor channel layers 110, which will be used to form the channel regions of the semiconductor device. According to an exemplary embodiment, reactive ion etching (RIE) is used to etch through the sacrificial semiconductor layers 108 and semiconductor channel layers 110 to form the nanosheet fin 210.

In one or more embodiments, portions of the semiconductor substrate 102 can also be removed during the etching step to form shallow trench isolation (STI) regions 204.

The process of forming the STI regions 204 is standard and well-known in the art, it typically involves depositing an insulating material to substantially fill areas of the semiconductor structure 100 between adjacent (not shown) nanosheet fins 210 for electrically isolating the nanosheet fins 210. The STI regions 204 may be formed by, for example, CVD of a dielectric material. Non-limiting examples of dielectric materials to form the STI regions 204 include silicon oxide, silicon nitride, hydrogenated silicon carbon oxide, silicon based low-k dielectrics, flowable oxides, porous dielectrics, or organic dielectrics including porous organic dielectrics. After forming the STI regions 204, the fin hardmask (not shown) can be removed from the semiconductor structure 100 using any suitable etching technique.

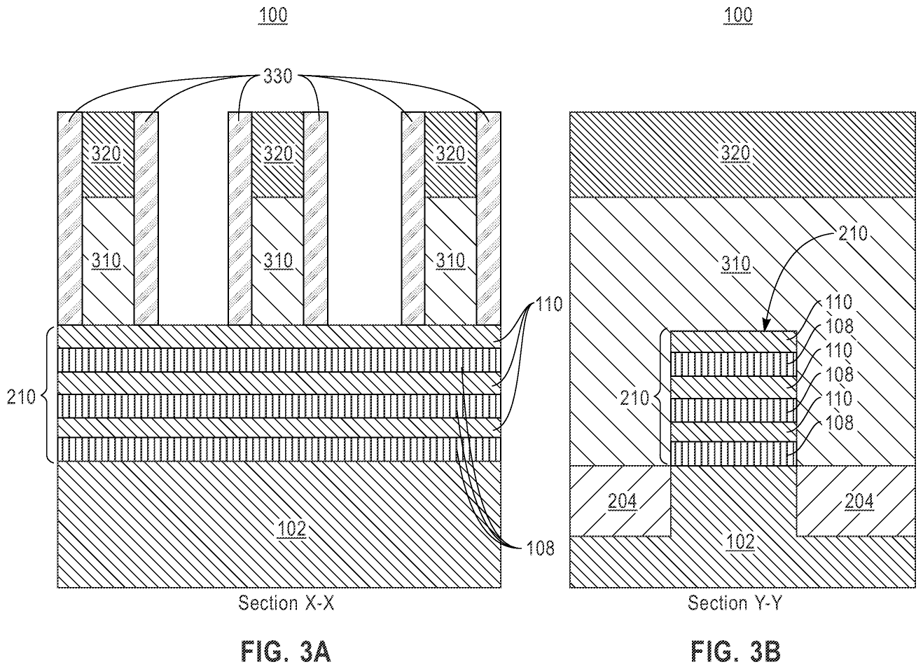

Referring now to FIGS. 3A-3B, cross-sectional views of the semiconductor structure 100 are shown after forming a dummy gate 310, a sacrificial hardmask 320 and sidewall gate spacer 330, according to an embodiment of the present disclosure. In this embodiment, FIG. 3A is a cross-sectional view of the semiconductor structure 100 taken along line X-X, as depicted in FIG. 1, and FIG. 3B is a cross-sectional view of the semiconductor structure 100 taken along line Y-Y, as depicted in FIG. 1.

In one or more embodiments, the dummy gate 310 and sacrificial hardmask 320 form a sacrificial gate structure for the semiconductor structure 100. The dummy gate 310 is formed above a topmost semiconductor channel layer 110. The process of forming the dummy gate 310 and sacrificial hardmask 320 is typical and well-known in the art. In one or more embodiments, the dummy gate 310 is formed from amorphous silicon (a-Si), and the sacrificial hardmask 320 is formed from silicon nitride (SiN), silicon oxide, an oxide/nitride stack, or similar materials and configurations.

As known by those skilled in the art, the dummy gate 310 is subsequently patterned, as depicted in FIG. 3A. The process of patterning the dummy gate 310 typically involves exposing a pattern on a photoresist layer and transferring the pattern to the sacrificial hardmask 320 and dummy gate 310 using known lithography and RIE processing.

Typically, after patterning the dummy gate 310, a spacer material can be deposited along sidewalls of the dummy gate 310 and along sidewalls of the sacrificial hardmask 320 to form the sidewall gate spacer 330 shown in FIG. 3A. The sidewall gate spacer 330 can be formed using a spacer pull down formation process. The sidewall gate spacer 330 can also be formed using a sidewall image transfer (SIT) spacer formation process, which includes spacer material deposition followed by directional RIE of the deposited spacer material.

In one or more embodiments, the spacer material can also be deposited in a space between the nanosheet fin 210 and the semiconductor substrate 102. In such embodiments, the deposited spacer material can be referred to as a bottom dielectric isolation layer (not shown in the figures). In some embodiments, the bottom dielectric isolation layer (not shown) and the sidewall gate spacer 330 may be composed of different materials.

Non-limiting examples of various spacer materials for forming the sidewall gate spacer 330 and bottom dielectric isolation layer (not shown) may include conventional low-k materials such as SiO₂, SiOC, SiOCN, or SiBCN. Typically, a thickness of the sidewall gate spacer 330 may vary from approximately 5 nm to approximately 20 nm, and ranges therebetween.

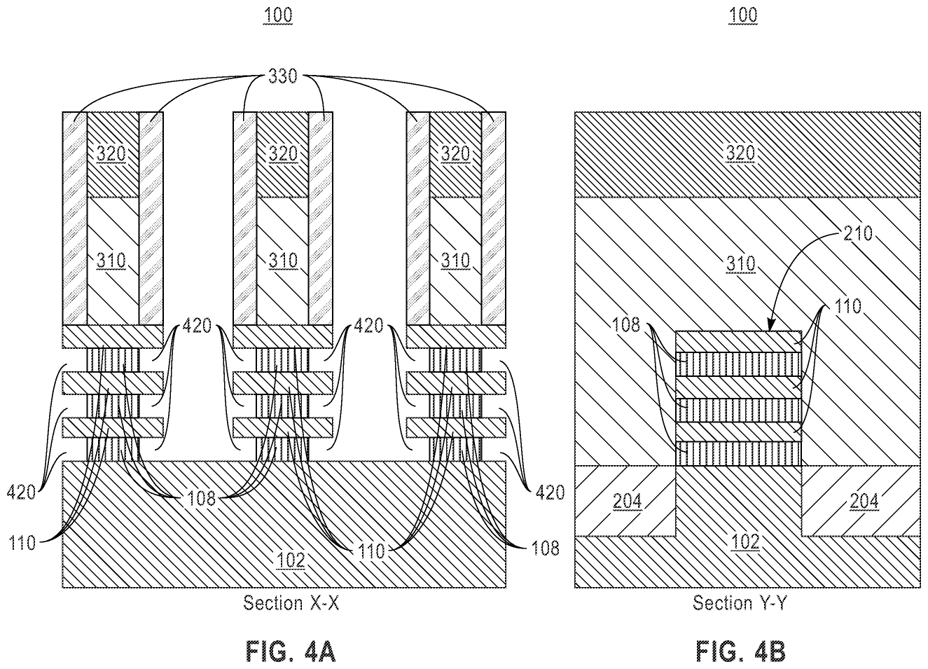

Referring now to FIGS. 4A-4B, cross-sectional views of the semiconductor structure 100 are shown after recessing the nanosheet fin 210 (FIG. 3A) and selectively etching the sacrificial semiconductor layers 108, according to an embodiment of the present disclosure. In this embodiment, FIG. 4A is a cross-sectional view of the semiconductor structure 100 taken along line X-X, as depicted in FIG. 1, and FIG. 4B is a cross-sectional view of the semiconductor structure 100 taken along line Y-Y, as depicted in FIG. 1.

According to an embodiment, the sidewall gate spacer 330 can be used as a mask, to recess portions of the nanosheet fin 210 that are not covered by the sidewall gate spacer 330 and dummy gate 310, as illustrated in the figure. For example, a RIE process can be used to recess the portions of the nanosheet fin 210 that are not under the sidewall gate spacer 330 and dummy gate 310. According to an embodiment, the nanosheet fin 210 can be recessed until an uppermost surface of the semiconductor substrate 102.

After patterning the nanosheet fin 210, outer portions of each of the sacrificial semiconductor layers 108 are selectively recessed using, for example, a selective etch process such as a hydrogen chloride (HCL) gas etch. Preferably, the selected etch process for recessing the sacrificial semiconductor layers 108 is capable of etching silicon germanium without attacking silicon. Etching outer portions of the sacrificial semiconductor layer 108 form indentation regions or first recesses 420 between semiconductor channel layers 110, as depicted in FIG. 4A. As mentioned above, etching of the sacrificial semiconductor layers 108 defines a nominal gate length (L_{g}) for the semiconductor structure 100.

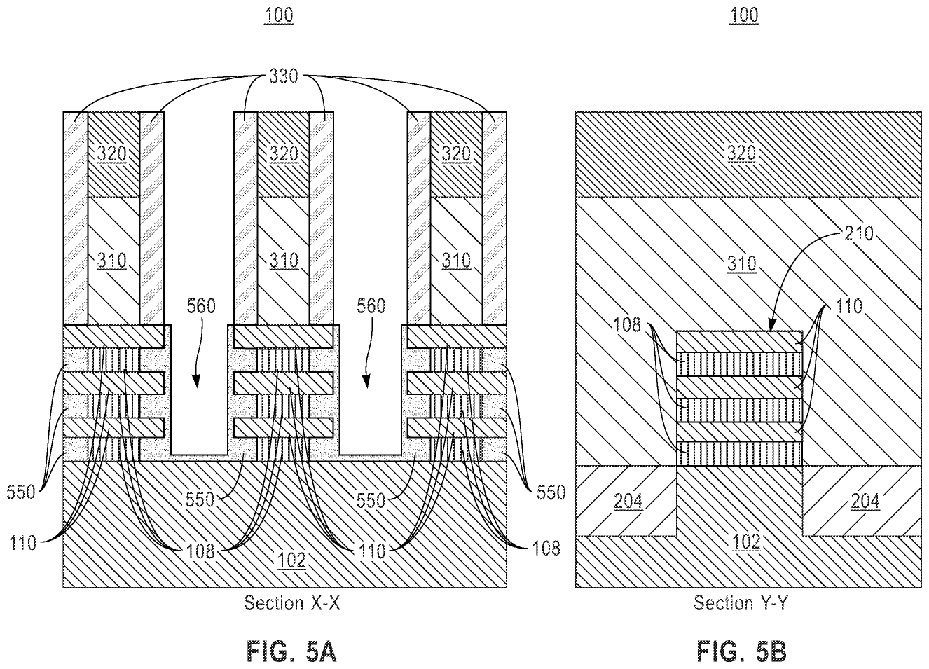

Referring now to FIGS. 5A-5B, cross-sectional views of the semiconductor structure 100 are shown after forming a first epitaxial layer 550, according to an embodiment of the present disclosure. In this embodiment, FIG. 5A is a cross-sectional view of the semiconductor structure 100 taken along line X-X, as depicted in FIG. 1, and FIG. 5B is a cross-sectional view of the semiconductor structure 100 taken along line Y-Y, as depicted in FIG. 1.

According to an embodiment, the first epitaxial layer 550 can be formed in the semiconductor structure 100 using an epitaxial growth process. Specifically, the first epitaxial layer 550 is formed above the semiconductor substrate 102, within the first recesses 402 (FIG. 4A) and off opposing sidewalls (i.e., outer edges) of the semiconductor channel layers 110. Thus the first epitaxial layer 550 may grow from all exposed surfaces of the semiconductor substrate 102, sacrificial semiconductor layers 108 (i.e., SiGe layers), and semiconductor channel layers 110 (i.e., Si layers).

As depicted in FIG. 5A, the first epitaxial layer 550 substantially fills the first recesses 402 (FIG. 4A). Stated differently, the first epitaxial layer 550 is formed above a perimeter of the semiconductor structure 100 formed by an exposed surface of the semiconductor substrate 102, exposed surfaces of the sacrificial semiconductor layers 108 and outer edges of the semiconductor channel layers 110. In one or more embodiments, the first epitaxial layer 550 provides a silicon-based buffer epitaxy layer that pinches-off the first recesses 420 shown in FIG. 4A (i.e., inner spacer region) and separates the gate structure from subsequently formed source/drain regions, as will be described in detail below. According to an embodiment, forming the first epitaxial layer 550 may enable targeted L_{g} without forming dielectric inner spacers.

With continued reference to FIGS. 5A-5B, in embodiments in which the semiconductor structure 100 is a p-FET device, the first epitaxial layer 550 includes, for example, epitaxially grown silicon (Si) or boron-doped silicon (Si:B). In embodiments in which the semiconductor structure 100 is an n-FET device, the first epitaxial layer 550 includes, for example, epitaxially grown phosphorus-doped silicon (Si:P). According to an exemplary embodiment, the first epitaxial layer 550 may be formed to a thickness of approximately 2 nm to approximately 10 nm, and ranges therebetween. After forming the first epitaxial layer 550, second recesses 560 remain between adjacent nanosheet fins 210, as shown in FIG. 5A.

It should be noted that due to the absence of a dielectric inner spacer, a substantially conformal first epitaxial layer 550 can be achieved in the semiconductor structure 100, which may be advantageous for device strain engineering and enhancing device performance.

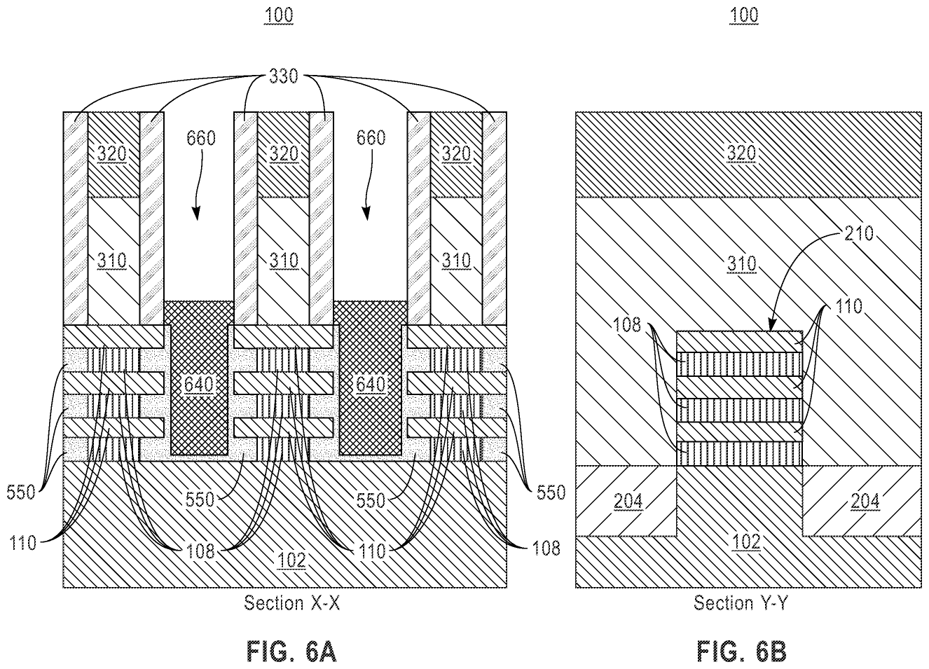

Referring now to FIGS. 6A-6B, cross-sectional views of the semiconductor structure 100 are shown after forming a second epitaxial layer within the second recesses 560 depicted in FIG. 5A, according to an embodiment of the present disclosure. In this embodiment, FIG. 6A is a cross-sectional view of the semiconductor structure 100 taken along line X-X, as depicted in FIG. 1, and FIG. 6B is a cross-sectional view of the semiconductor structure 100 taken along line Y-Y, as depicted in FIG. 1.

According to an embodiment, the second epitaxial layer formed within the second recesses 560 (FIG. 5A) provides source/drain regions 640 for the semiconductor structure 100. The source/drain regions 640 can be formed using an epitaxial layer growth process on the exposed portions of the first epitaxial layer 550.

As depicted in FIG. 6A, the source/drain regions 640 are formed on a exposed uppermost surface of the first epitaxial layer 550. It should be noted that this configuration is different from traditional nanosheet architecture in which sides of the nanosheet fins (e.g., nanosheet fins 210) are in direct contact with end portions of the semiconductor channel layers (e.g., semiconductor channel layers 110) and end portions of inner spacers typically formed surrounding sacrificial semiconductor layers (e.g., sacrificial semiconductor layers 108). In this embodiment, the source/drain regions 640 are disposed above a horizontal portion of the first epitaxial layer 550 formed above the semiconductor substrate 102.

Similar to the first epitaxial layer 550, the second epitaxial layer forming the source/drain regions 640 includes, for example, epitaxially grown Si:B in embodiments in which the semiconductor structure 100 is a p-FET device. In embodiments in which the semiconductor structure 100 is an n-FET device, the second epitaxial layer forming the source/drain regions 640 includes, for example, epitaxially grown Si:P. The second epitaxial layer forming the source/drain regions 640 can be grown until reaching a bottom portion of the sidewall spacer 330. According to an embodiment, owing to the presence of the first epitaxial layer 550, the source/drain regions 640 may achieve a shape that resembles the letter “T” or a T-shaped configuration, as shown in FIG. 6A. As used herein, the term “T-shaped” may refer to a shape including a horizontal segment (or region) connected or linked on a middle point with a vertical segment in the shape of the letter “T”. Third recesses 660 may remain above the source/drain region 640, as depicted in FIG. 6A. It should be noted that source/drain regions 640 and first epitaxial layer 550 can be used to generate a compressive or tensile strain on the semiconductor channel layers 110 for improving carrier mobility in the channel region and hence device performance. As known by those skilled in the art, the compressive or tensile strain will depend on the type of materials used to form source/drain regions 640 and first epitaxial layer 550.

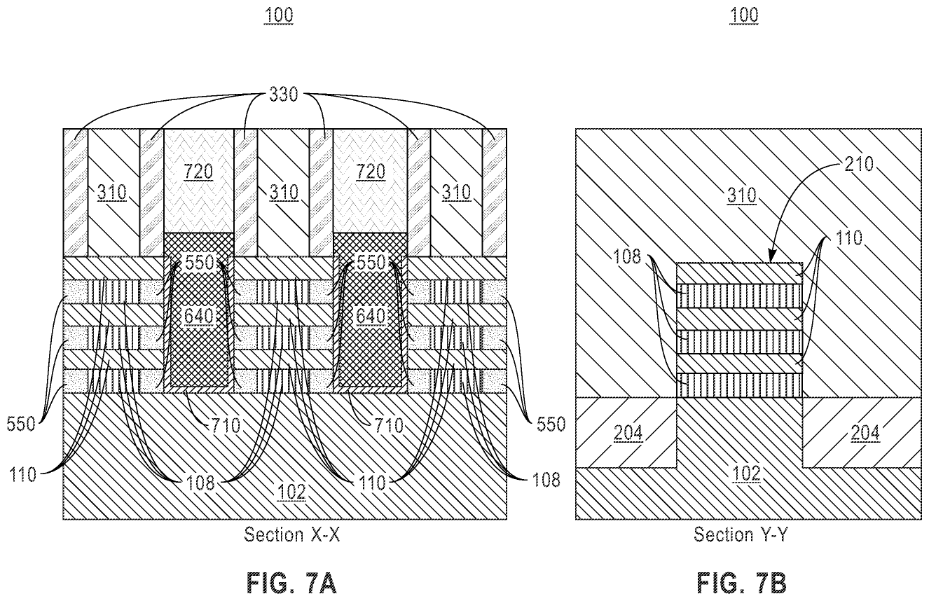

In this embodiment, it should be noted that dopants from source/drain regions 640 including germanium (Ge) atoms can diffuse during epitaxial growth processes and subsequent thermal budget (e.g., high temperature annealing) forming a diffusion region 710 that is located at an interface between the source/drain regions 640 and opposite outer sidewalls of the semiconductor channel layers 110, opposite outer sidewalls of the first epitaxial layer 550 and an uppermost portion of the semiconductor substrate 102, as depicted in FIG. 7A. In one or more embodiments, the diffusion region 710 may provide a common boundary between the source/drain regions 640, the first epitaxial layer 550, the semiconductor channel layers 110, and the semiconductor substrate 102. It should also be noted that the extension of the diffusion region 710 may depend on the applicable thermal budget. The diffusion region 710 provides a transition region in which dopant atoms (e.g., Ge) can diffuse into the semiconductor channel layers 110 (i.e., Si layers) bringing dopant atoms closer to the channel region of the semiconductor structure 100. This may be particularly beneficial for p-FET devices.

As depicted in FIG. 7A, the diffusion region 710 has a U-shaped perimeter that substantially surrounds the source/drain regions 640. As used herein, the term “U-shaped” may refer to a shape including two vertical segments (or regions) parallel to each other, the two vertical segments being connected or linked on one end by a horizontal segment in the shape of the letter “U”.

In some embodiments, a p-FET region of the semiconductor structure 100 may include a p-FET device configured with the first epitaxial layer 550 and diffusion region 710, while an n-FET region of the semiconductor structure 100 may include an n-FET device having a typical configuration including dielectric inner spacers instead of the first epitaxial layer 550.

Referring now to FIGS. 7A-7B, cross-sectional views of the semiconductor structure 100 are shown after forming a first dielectric layer 720 and conducting a planarization process, according to an embodiment of the present disclosure. In this embodiment, FIG. 7A is a cross-sectional view of the semiconductor structure 100 taken along line X-X, as depicted in FIG. 1, and FIG. 7B is a cross-sectional view of the semiconductor structure 100 taken along line Y-Y, as depicted in FIG. 1.

At this step of the manufacturing process, the first dielectric layer 720 is formed to fill voids in the semiconductor structure 100. Specifically, the first dielectric layer 720 fills a space remaining (i.e., third recesses 660 shown in FIG. 6A) above the source/drain regions 640. The first dielectric layer 720 can be formed by, for example, CVD of a dielectric material. Non-limiting examples of dielectric materials to form the first dielectric layer 720 may include silicon oxide, silicon nitride, hydrogenated silicon carbon oxide, silicon based low-k dielectrics, flowable oxides, porous dielectrics, or organic dielectrics including porous organic dielectrics.

After deposition of the first dielectric layer 720, a planarization process, such as a chemical mechanical polishing (CMP), can be conducted on the semiconductor structure 100. This process may expose a top surface of the dummy gate 310 in preparation for removal of the dummy gate 310 (i.e., gate replacement).

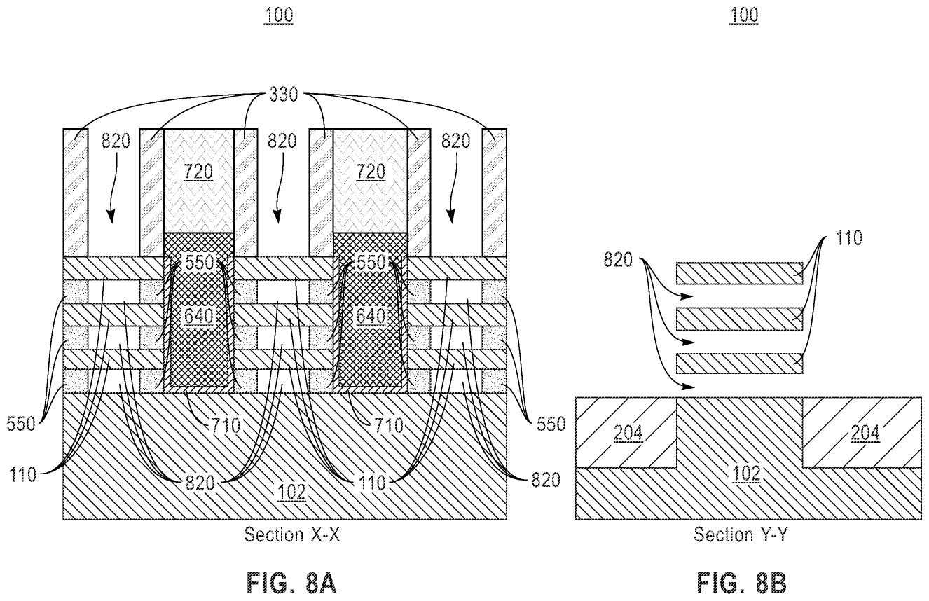

Referring now to FIGS. 8A-8B, cross-sectional views of the semiconductor structure 100 are shown after removing the dummy gate 310 (FIG. 7A) and the sacrificial semiconductor layers 108 (FIGS. 7A-7B), according to an embodiment of the present disclosure. In this embodiment, FIG. 8A is a cross-sectional view of the semiconductor structure 100 taken along line X-X, as depicted in FIG. 1, and FIG. 8B is a cross-sectional view of the semiconductor structure 100 taken along line Y-Y, as depicted in FIG. 1.

The dummy gate 310 (FIGS. 7A-7B) can be removed using known etching processes including, for example, RIE or chemical oxide removal (COR). In a gate-last fabrication process, the removed dummy gate 310 (FIGS. 7A-7B) is thereafter replaced with a metal gate as known in the art.

In this embodiment, the sacrificial semiconductor layers 108 (FIGS. 7A-7B) are also removed from the semiconductor structure 100. In an exemplary embodiment, the sacrificial semiconductor layers 108 can be removed by known etching processes including, for example, RIE, wet etch or dry gas (HCl). Removal of the dummy gate 310 (FIGS. 7A-7B) and sacrificial semiconductor layers 108 (FIGS. 7A-7B) create fourth recesses 820 located between opposing inner sidewalls of the first epitaxial layer 550 and semiconductor channel layers 110. The fourth recesses 820 also expose a topmost semiconductor channel layer 110 and opposing inner sidewalls of the sidewall spacer 330. As known by those skilled in the art, the fourth recesses 820 will be subsequently filled with corresponding work function metals, as will be described in detail below.

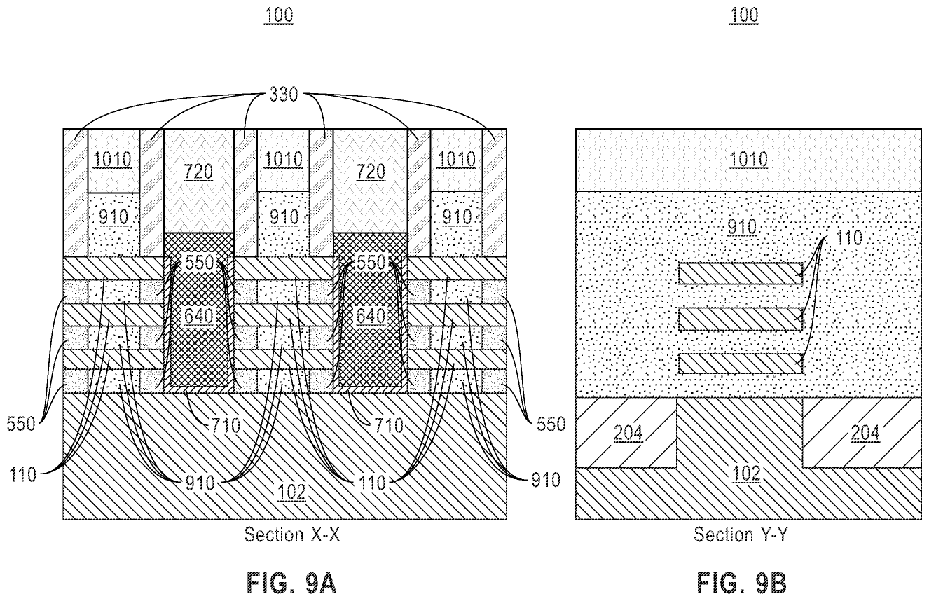

Referring now to FIGS. 9A-9B, cross-sectional views of the semiconductor structure 100 are shown after forming a replacement metal gate structure, according to an embodiment of the present disclosure. In this embodiment, FIG. 9A is a cross-sectional view of the semiconductor structure 100 taken along line X-X, as depicted in FIG. 1, and FIG. 9B is a cross-sectional view of the semiconductor structure 100 taken along line Y-Y, as depicted in FIG. 1.

In this step, a metal gate stack 910 and a self-aligned contact cap (hereinafter referred to as “metal cap”) 1010 are formed in the semiconductor structure 100. Although not shown in the figures, the metal gate stack 910 further includes a gate dielectric stack that is typically formed before depositing work function metals and metal cap 1010. In one or more embodiments, the gate dielectric stack (not shown) may include a layer of silicon oxide and a layer of a high-k dielectric material, such as a hafnium-based material.

The metal gate stack 910 is formed within the fourth recesses 820 shown in FIGS. 8A-8B. The metal gate stack 910 may include the gate dielectric stack (not shown) and one or more work function metals such as, but not limited to, titanium nitride (TiN), tantalum nitride (TaN), titanium carbide (TiC), titanium aluminum carbide (TiAIC), and conducting metals including, for example, aluminum (Al), tungsten (W) or cobalt (Co). The gate cap 1010 is subsequently formed above the metal gate stack 910. The material forming the gate cap 1010 may fill any remaining opening between the metal gate stack 910 and sidewall spacer 330. The material forming the gate cap 1010 may be aluminum oxide (AlOx), although other materials such as silicon nitride (SiN) may also or alternatively be used.

After forming the metal gate stack 910 and the gate cap 1010, a chemical mechanical polishing (CMP) may be conducted to remove excess material and polish upper surfaces of the semiconductor structure 100.

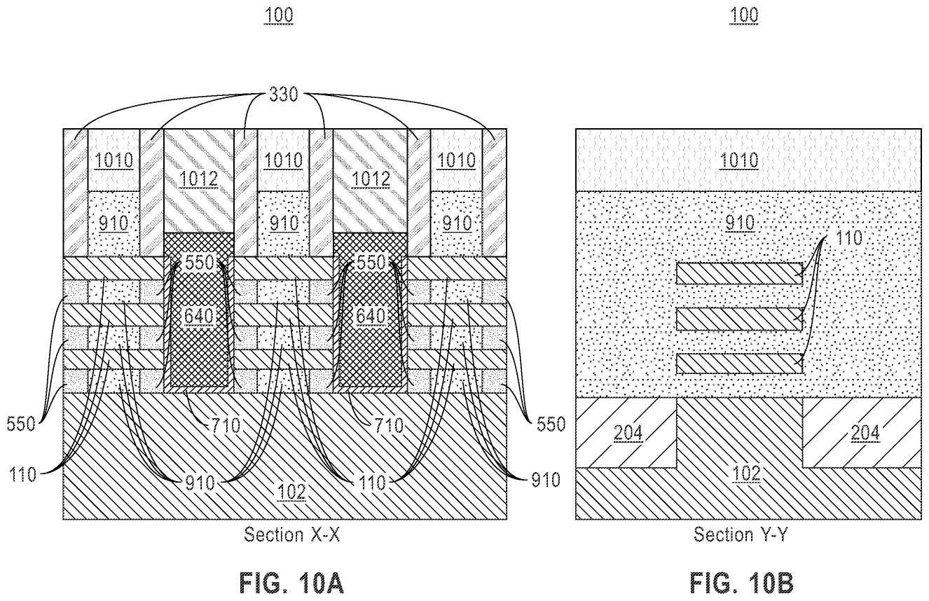

Referring now to FIGS. 10A-10B, cross-sectional views of the semiconductor structure 100 are shown after contact metallization, according to an embodiment of the present disclosure. In this embodiment, FIG. 10A is a cross-sectional view of the semiconductor structure 100 taken along line X-X, as depicted in FIG. 1, and FIG. 10B is a cross-sectional view of the semiconductor structure 100 taken along line Y-Y, as depicted in FIG. 1.

As illustrated in FIG. 10A, the first dielectric layer 720 is removed using any suitable etching technique and replaced with a contact metal to form source/drain contacts 1012. The source/drain contacts 1012 are in contact with an uppermost surface of the source/drain regions 640. Stated differently, source/drain contacts 1012 are electrically connected to the source/drain regions 640. The process of forming the source/drain contacts 1012 is standard and well-known in the art. Typically, the process includes forming trenches (e.g., by removing the first dielectric layer 720) and subsequently filling the trenches with a conductive material or a combination of conductive materials to form the source/drain contacts 1012. The conductive material filling the source/drain contacts 1012 includes a conductive metal, for example, aluminum (Al), platinum (Pt), gold (Au), tungsten (W), titanium (Ti), Cobalt (Co) or any combination thereof. The conductive material may be deposited by a suitable deposition process, for example, CVD, PECVD, PVD, plating, thermal or e-beam evaporation, or sputtering. A planarization process, for example, CMP, is performed to remove any conductive material from upper surfaces of the semiconductor structure 100.

Although not shown in the figures, gate contacts to the metal gate stack 910 may also be formed on the semiconductor structure 100 using similar conductive materials and analogous processing techniques as for the source/drain contacts 1012.

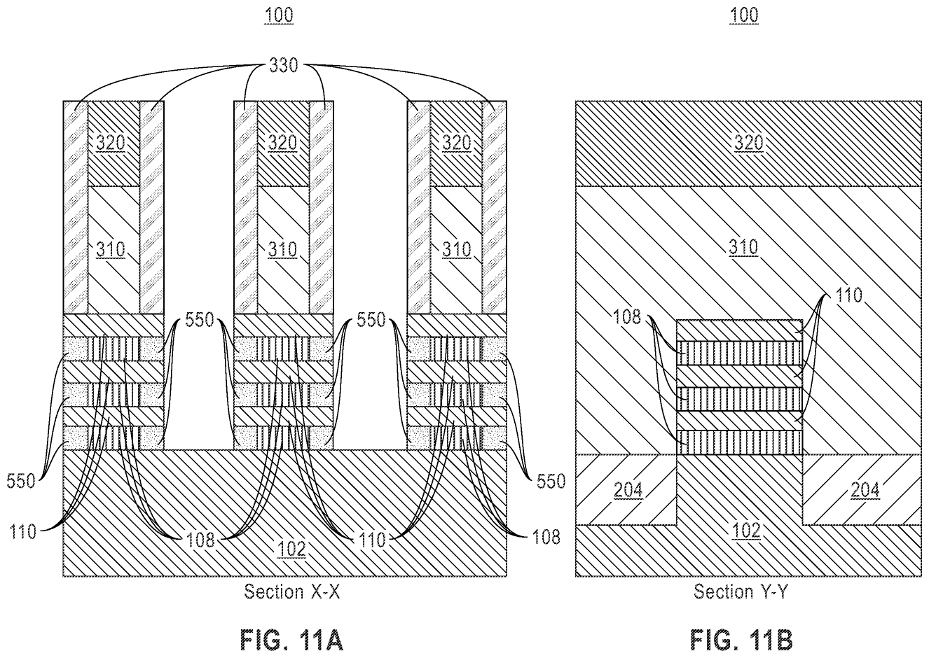

The following described embodiments provide alternative ways of forming a gate-all-around device without dielectric inner spacers. It should be noted that known and/or previously described semiconductor fabrication operations have been used to form the semiconductor structure 100 as depicted in FIGS. 11A-22B. Thus, conventional and previously described techniques related to semiconductor device and integrated circuit (IC) fabrication will not be described in detail herein to avoid unnecessarily obscuring the presented embodiments.

Referring now to FIGS. 11A-11B, cross-sectional views of the semiconductor structure 100 are shown after recessing the nanosheet fin 210, selectively etching the sacrificial semiconductor layers 108, growing the first epitaxial layer 550, and trimming the first epitaxial layer 550, according to an alternate embodiment of the present disclosure. In this embodiment, FIG. 11A is a cross-sectional view of the semiconductor structure 100 taken along line X-X, as depicted in FIG. 1, and FIG. 11B is a cross-sectional view of the semiconductor structure 100 taken along line Y-Y, as depicted in FIG. 1.

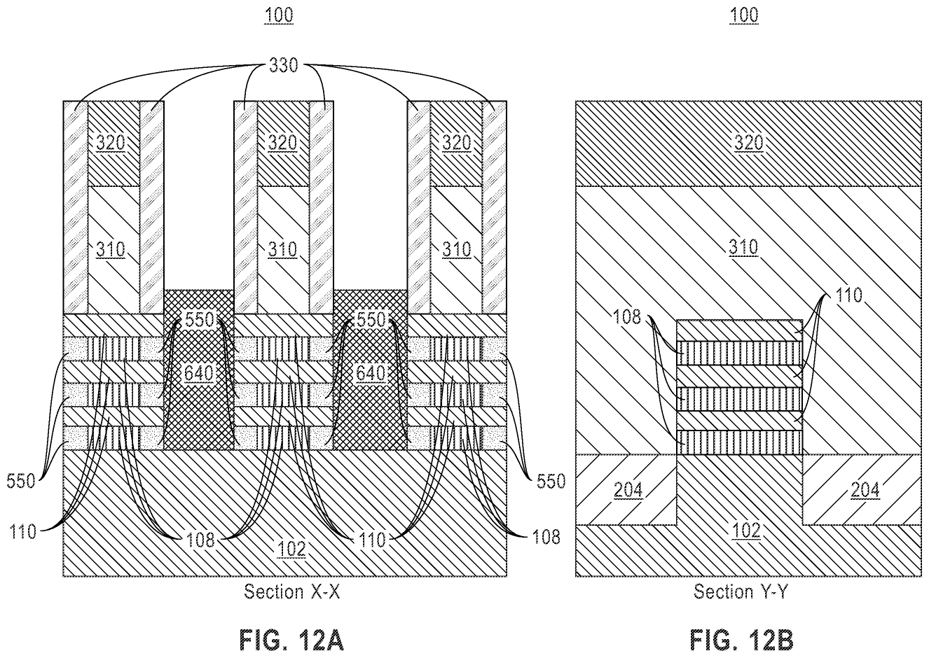

Semiconductor fabrication process described above with references to FIGS. 1A-5B have been applied to the semiconductor structure 100 depicted in FIGS. 11A-11B. It should be noted that the process of growing the first epitaxial layer 550 is conducted following processing steps described above in FIGS. 5A-5B. However, in this embodiment, prior to forming the source/drain regions 640 (depicted in FIG. 12A), an isotropic trimming process is conducted on the first epitaxial layer 550 such that outer sidewalls of the first epitaxial layer 550 are vertically aligned with outer sidewalls of each of the semiconductor channel layers 110 and outer sidewalls of the sidewall gate spacer 330, as depicted in FIG. 11A.

Stated differently, a first portion of the first epitaxial layer 550 extending outwards from the channel semiconductor layers 110 and a second portion of the first epitaxial layer 550 disposed above the semiconductor substrate 102 are removed from the semiconductor structure 100 such that the first epitaxial layer 550 substantially fills the first recesses 420 (FIGS. 4A-4B) and an outer (vertical) surface of the first epitaxial layer 550 is substantially flushed with an outer (vertical) surface of the channel semiconductor layers 110. As depicted in FIG. 11A, removal of the second portion of the first epitaxial layer 550 exposes an uppermost portion of the semiconductor substrate 102 located between nanosheet fins 210.

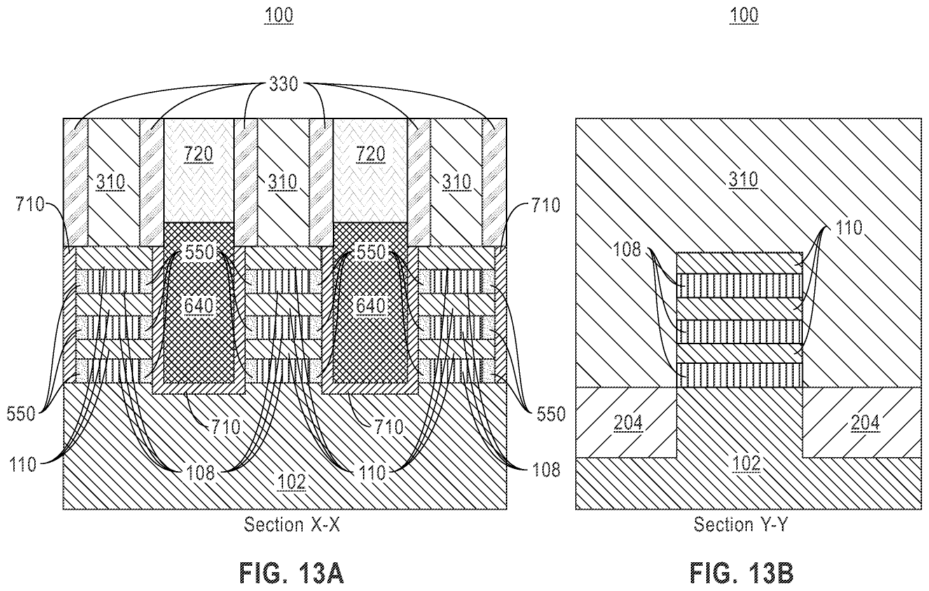

Referring now to FIGS. 12A-12B and FIGS. 13A-13B simultaneously, cross-sectional views of the semiconductor structure 100 are shown after forming the source/drain regions 640, first dielectric layer 720, and conducting a planarization process, according to an alternate embodiment of the present disclosure. In this embodiment, FIGS. 12A and 13A are cross-sectional views of the semiconductor structure 100 taken along line X-X, as depicted in FIG. 1, and FIGS. 12B and 13B are cross-sectional views of the semiconductor structure 100 taken along line Y-Y, as depicted in FIG. 1.

In the depicted embodiment, outer sidewalls of the source/drain regions 640 are in direct contact and vertically aligned with the semiconductor channel layers 110 due to the trimming process conducted on the first epitaxial layer 550. Unlike the embodiment described in FIGS. 6A-6B, in which the source/drain regions 640 include a T-shaped configuration due to the presence of the first epitaxial layer 550 between source/drain regions 640 and semiconductor channel layers 110.

As described above, dopant atoms can diffuse during epitaxial growth and subsequent thermal budget forming the diffusion region 710, as depicted in FIG. 13A. In this embodiment, the diffusion region 710 is formed by diffusion of dopant atoms including Ge atoms from the source/drain regions 640 into the outer sidewalls of the first epitaxial layer 550, outer sidewalls of the semiconductor channel layers 110, and an uppermost portion of the semiconductor substrate 102 located between adjacent nanosheet fins 210. As described above, the diffusion region 710 has a U-shaped perimeter that substantially surrounds the source/drain regions 640 and provides a common boundary between the first epitaxial layer 550, semiconductor channel layers 110, and uppermost portion of the semiconductor substrate 102. Specifically, in this embodiment, diffusion of dopant atoms (i.e., Ge) can occur towards the semiconductor channel layers 110, first epitaxial layer 550 and semiconductor substrate 102 due to the absence of the first epitaxial layer 550 from opposing sidewalls of the semiconductor channel layers 110 and from uppermost portions of the semiconductor substrate 102.

As previously described, after forming the source/drain regions 640 the first dielectric layer 720 can be deposited in the semiconductor structure 100 followed by a planarization process.

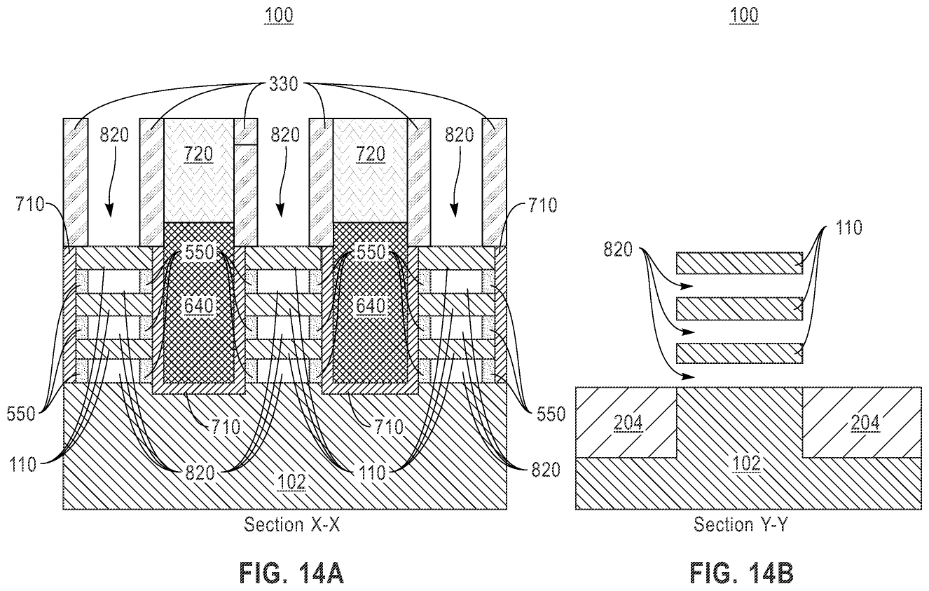

Referring now to FIGS. 14A-14B, FIGS. 15A-15B and FIGS. 16A-16B simultaneously, cross-sectional views of the semiconductor structure 100 are shown after removing the dummy gate 310, selectively removing the sacrificial semiconductor layers 108, forming the replacement metal gate structure, and forming metal contacts, according to an alternate embodiment of the present disclosure. In this embodiment, FIGS. 14A, 15A and 16A are cross-sectional views of the semiconductor structure 100 taken along line X-X, as depicted in FIG. 1, and FIGS. 14B, 15B and 16B are cross-sectional views of the semiconductor structure 100 taken along line Y-Y, as depicted in FIG. 1.

Processing steps conducted to form the semiconductor structure 100 as configured in FIGS. 14A-14B, FIGS. 15A-15B and FIGS. 16A-16B have been described in detail above. Thus, previously described techniques related to semiconductor device fabrication will not be described in detail herein to avoid unnecessarily obscuring the presented embodiments.

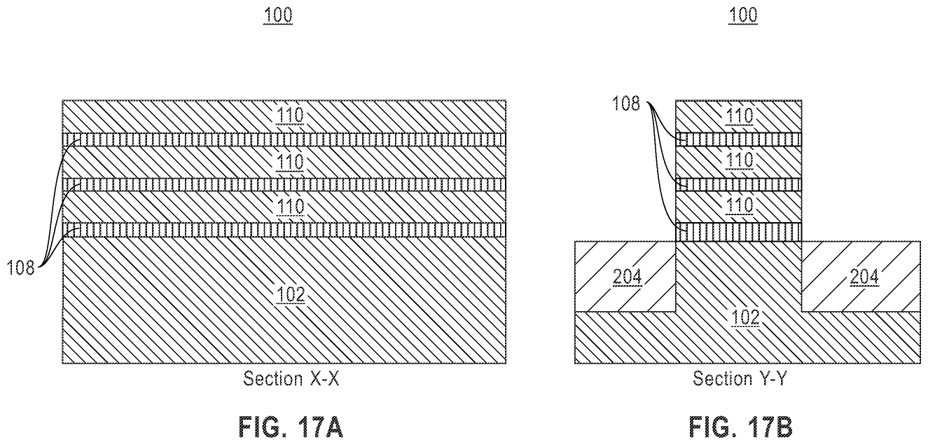

Referring now to FIGS. 17A-17B, cross-sectional views of the semiconductor structure 100 are shown after forming the nanosheet stack 202, patterning the nanosheet fin 210, and forming the STI regions 204, according to an alternate embodiment of the present disclosure. In this embodiment, FIG. 17A is a cross-sectional view of the semiconductor structure 100 taken along line X-X, as depicted in FIG. 1, and FIG. 17B is a cross-sectional view of the semiconductor structure 100 taken along line Y-Y, as depicted in FIG. 1.

Known semiconductor fabrication operations have been used to form the semiconductor structure 100 as depicted in FIGS. 17A-17B. In this embodiment, thinner sacrificial semiconductor layers 108 have been formed in the semiconductor structure 100, while the semiconductor channel layers 110 are substantially thicker than the semiconductor channel layers 110 depicted in FIGS. 2A-2B. In the depicted embodiment, the sacrificial semiconductor layers 108 may include a thickness varying from approximately 3 nm to approximately 10 nm, while the semiconductor channel layers 110 may include a thickness varying from approximately 7 nm to approximately 15 nm.

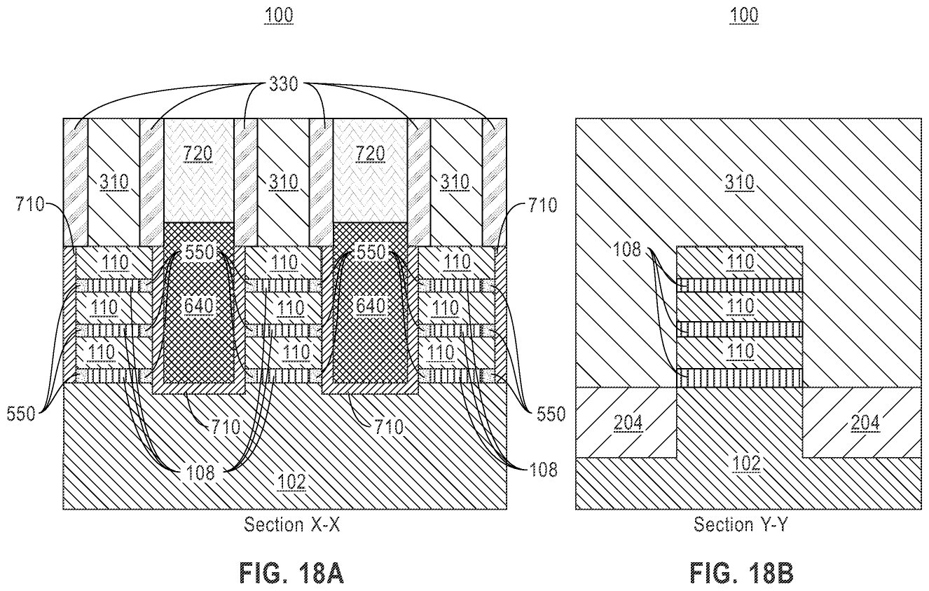

Referring now to FIGS. 18A-18B, cross-sectional views of the semiconductor structure 100 are shown after conducting various semiconductor fabrication processes including forming the dummy gate 310, sidewall gate spacer 330, recessing the nanosheet fin 210, selectively etching sacrificial semiconductor layer 108, forming the first epitaxial layer 550, forming source/drain regions 640, forming first dielectric layer 720, and conducting a planarization process, according to an alternate embodiment of the present disclosure. In this embodiment, FIG. 18A is a cross-sectional view of the semiconductor structure 100 taken along line X-X, as depicted in FIG. 1, and FIG. 18B is a cross-sectional view of the semiconductor structure 100 taken along line Y-Y, as depicted in FIG. 1.

According to an embodiment, semiconductor fabrication process described above with references to FIGS. 1A-7B have been applied to form the semiconductor structure 100 as depicted in FIGS. 18A-18B. It should be noted that, the process of growing the first epitaxial layer 550 is conducted following the steps described above in FIGS. 5A-5B. However, in this embodiment, prior to forming the source/drain regions 640, an isotropic trimming process is conducted on the first epitaxial layer 550 such that outer sidewalls of the first epitaxial layer 550 are vertically aligned with outer sidewalls of each of the semiconductor channel layers 110 and outer sidewalls of the sidewall gate spacer 330. Stated differently, a first portion of the first epitaxial layer 550 extending outwards from the channel semiconductor layers 110 and a second portion of the first epitaxial layer 550 disposed above the semiconductor substrate 102 are removed from the semiconductor structure 100 such that the first epitaxial layer 550 substantially fills an inner spacer region (e.g., first recesses 420 depicted in FIGS. 4A-4B) and an outer (vertical) surface of the first epitaxial layer 550 is substantially flushed with an outer (vertical) surface of the channel semiconductor layers 110.

As described above, due to the trimming process conducted on the first epitaxial layer 550, sidewalls of the source/drain regions 640 are in contact with the semiconductor channel layers 110. In this embodiment, dopant atoms from source/drain regions 640 including germanium (Ge) atoms can diffuse during epitaxial growth and subsequent thermal budget forming the diffusion region 710. In this embodiment, the diffusion region 710 provides a common boundary between the source/drain regions 640, the first epitaxial layer 550 and the semiconductor channel layers 110. Specifically, in this embodiment, diffusion of dopant atoms can occur towards the semiconductor channel layers 110, first epitaxial layer 550 and semiconductor substrate 102 due to the absence of the first epitaxial layer 550 along opposing sidewalls of the semiconductor channel layers 110 and above the semiconductor substrate 102.

As previously described, after forming the source/drain regions 640 the first dielectric layer 720 can be deposited in the semiconductor structure 100 followed by a planarization process.

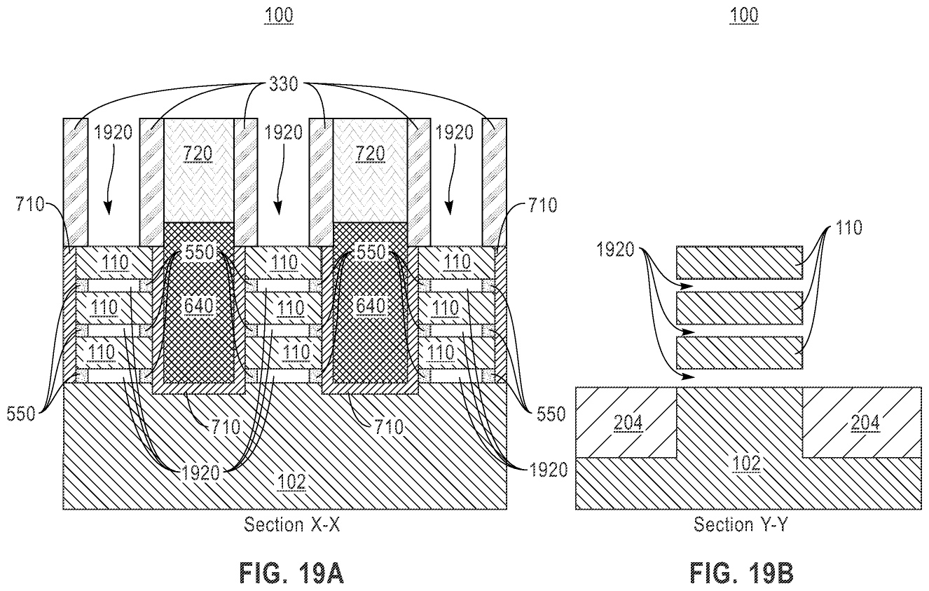

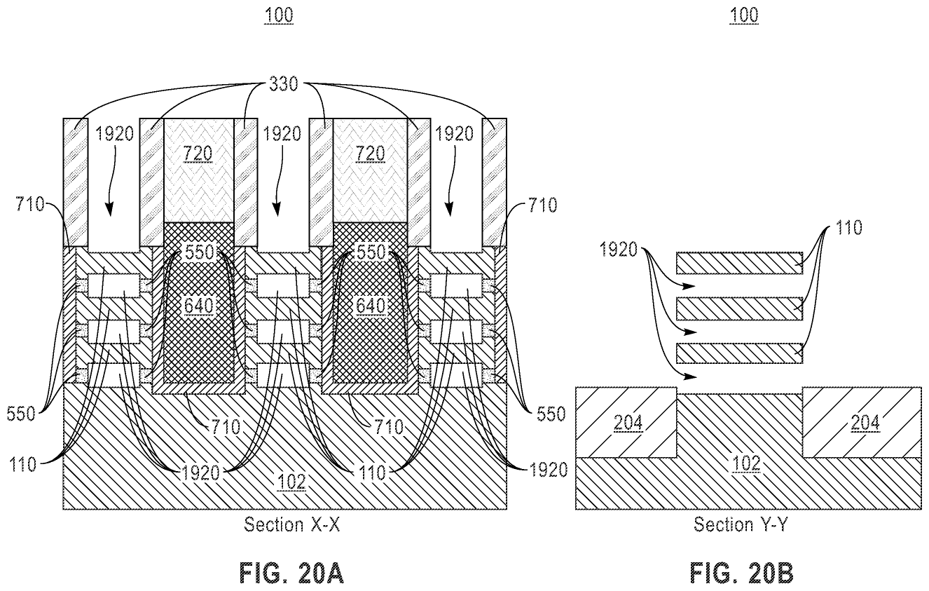

Referring now to FIGS. 19A-19B and FIGS. 20A-20B simultaneously, cross-sectional views of the semiconductor structure 100 are shown after removing the dummy gate 310, selectively removing the sacrificial semiconductor layers 108, and etching the semiconductor channel layers 110, according to an alternate embodiment of the present disclosure. In this embodiment, FIGS. 19A and 20A are cross-sectional views of the semiconductor structure 100 taken along line X-X, as depicted in FIG. 1, and FIGS. 19B and 20B are cross-sectional views of the semiconductor structure 100 taken along line Y-Y, as depicted in FIG. 1.

In this embodiment, fifth recesses 1920 remain in the semiconductor structure 100 after removing the dummy gate 310 and the sacrificial semiconductor layers 108 (FIGS. 18A-18B). The fifth recesses 1920 are located between channel semiconductor layer 110 and first epitaxial layer 550, as depicted in FIG. 19A. A selective etching process can be conducted on the semiconductor structure 100 to expand or enlarge the fifth recesses 1920 as illustrated in FIGS. 20A-20B. In an exemplary embodiment, cycles of finely controlled oxidation of the Si channel followed by selective silicon oxide etch can be used to selectively remove portions of the semiconductor channel layers 110. Each cycle allows nanometric control of the oxidation/removal. Selective Si removal causes the semiconductor channel layers 110 to have a shape resembling a dumbbell or dumbbell-like shape (i.e., thinner in the gate region and thicker towards the extension or source/drain region), as can be observed in FIG. 20A.

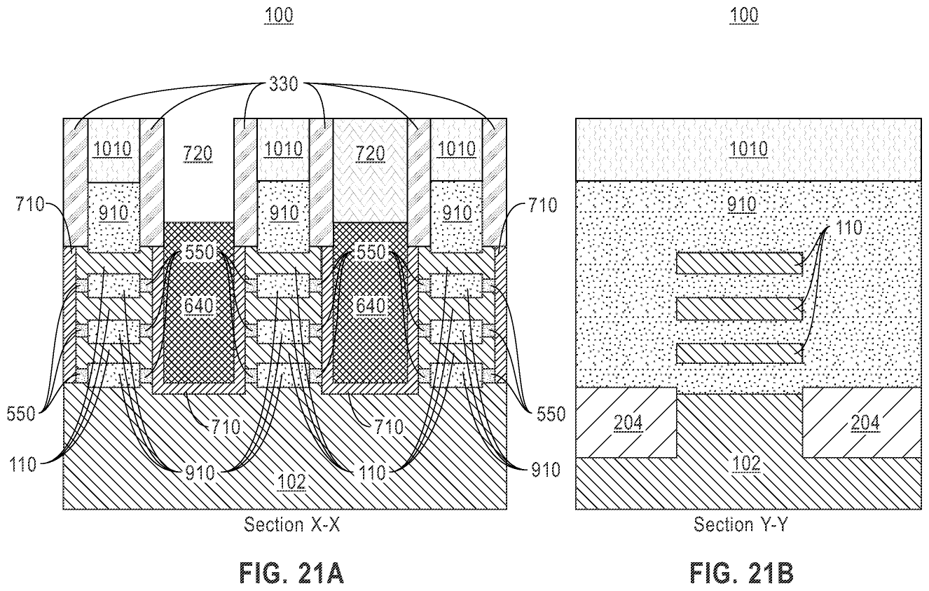

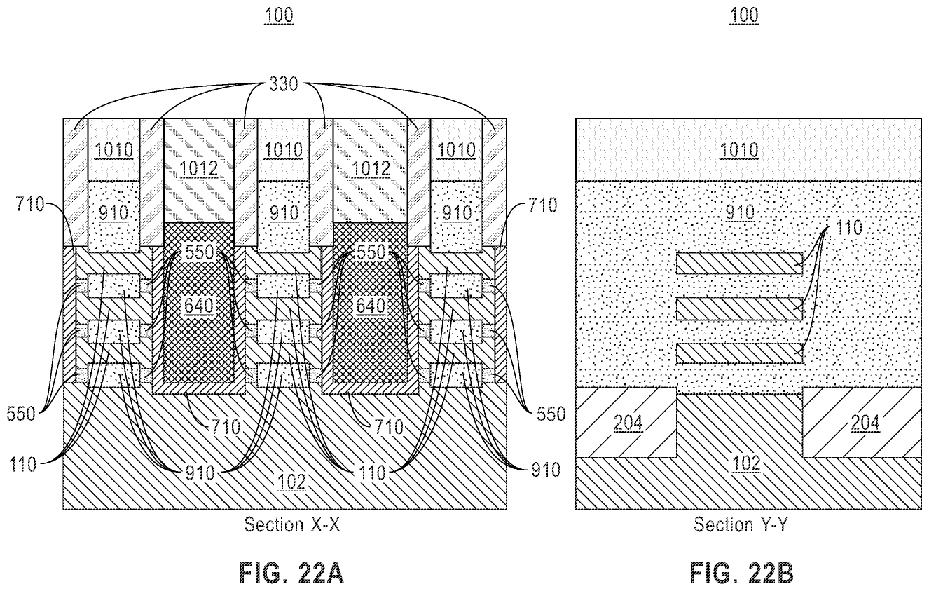

Referring now to FIGS. 21A-21B and FIGS. 22A-22B simultaneously, cross-sectional views of the semiconductor structure 100 are shown after forming a metal gate structure and contact metallization, according to an alternate embodiment of the present disclosure. In this embodiment, FIGS. 21A and 22A are cross-sectional views of the semiconductor structure 100 taken along line X-X, as depicted in FIG. 1, and FIGS. 21B and 22B are cross-sectional views of the semiconductor structure 100 taken along line Y-Y, as depicted in FIG. 1.

The enlarged fifth recesses 1920 (FIGS. 20A-20B) can be subsequently filled with the metal gate stack 910, as shown in FIGS. 21A-21B. As illustrated in FIGS. 22A-22B, the fabrication process continues by forming metal contacts, including the source/drain contacts 1012, using semiconductor techniques previously described. It should be noted that, in the depicted embodiment, the diffusion region 710 also exhibits an U-shaped perimeter that substantially surrounds the source/drain regions 640.

Thus, the previously described embodiments provide a semiconductor structure that includes a first gate-all-around device disposed on a first region of a substrate, the first gate-all-around device including a first metal gate stack surrounding a first channel layer, the first metal gate stack being separated from a first source/drain region by a dielectric inner spacer disposed on opposite sides of the first metal gate stack, and a second gate-all-around device disposed on a second region of the substrate, the second gate-all-around device including a second metal gate stack surrounding a second channel layer, the second metal gate stack being separated from a second source/drain region by an epitaxial layer disposed on opposite sides of the second metal gate stack.

According to an embodiment, the first gate-all-around device may be a n-FET device, and the second gate-all-around device is a p-FET device.

According to an embodiment, each of the first metal gate stack and the second metal gate stack further includes a gate dielectric material.

According to an embodiment, the second gate-all-around device further includes a second sidewall gate spacer located along opposite sidewalls of a portion of the second metal gate stack disposed above the second channel layer, wherein a thickness of the second sidewall gate spacer defines an extension region for the second gate-all-around device, and a diffusion region located within the extension region, the diffusion region including an outer portion of the second channel layer and an outer portion of the epitaxial layer.

According to an embodiment, the diffusion region is located at an interface between the second source/drain region, the second channel layer and the epitaxial layer, the diffusion region having a U-shaped perimeter that surrounds the second source/drain region, the diffusion region including diffused dopant atoms from the second source/drain region.

According to an embodiment, the second source/drain region and the epitaxial layer generate at least one of a compressive strain and a tensile strain on the second channel layer depending on a type of material selected to form the second source/drain region and the epitaxial layer.

According to an embodiment, a material forming the epitaxial layer includes at least one of Silicon (Si) and Silicon doped with Boron (Si:B), and a material forming the second source/drain region includes Silicon-Germanium doped with Boron (SiGe:B).

According to one or more embodiments of the present disclosure, a semiconductor structure includes a plurality of channel layers vertically stacked over a substrate, a metal gate stack including a gate dielectric material, the metal gate stack being located between the plurality of channel layers, an epitaxial layer disposed on opposite sides of the metal gate stack, a source/drain region adjacent to the plurality of channel layers and the epitaxial layer, and a diffusion region located at an interface between the source/drain region, the plurality of channel layers and the epitaxial layer, the diffusion region having a U-shaped perimeter that surrounds the source/drain region, the diffusion region including diffused dopant atoms from the source/drain region.

According to one or more embodiments, the metal gate stack surrounds the plurality of channel layers and is separated from the source/drain region by the epitaxial layer.

According to one or more embodiments, the source/drain region adjacent to the plurality of channel layers and the epitaxial layer generate at least one of a compressive strain and a tensile strain on the plurality of channel layers depending on a type of material selected to form the source/drain region and the epitaxial layer.

According to one or more embodiments, the semiconductor structure is a p-type transistor with the epitaxial layer comprising at least one of Si and Si:B, and the source/drain region comprising SiGe:B.

According to one or more embodiments, the semiconductor structure further includes a sidewall gate spacer located along opposite sidewalls of a portion of the metal gate stack disposed above an uppermost channel layer of the plurality of channel layers.

According to one or more embodiments, a portion of the epitaxial layer is located on opposite sides of each of the plurality of channel layers, the portion of the epitaxial layer extending outwards from the sidewall gate spacer.

According to one or more embodiments, outer sidewalls of the epitaxial layer are vertically aligned with outer sidewalls of the plurality of channel layers and outer sidewalls of the sidewall gate spacer.

According to one or more embodiments, the diffusion region further includes dopant atoms diffused within an outer portion of each of the plurality of channel layers and within an outer portion of the epitaxial layer.

According to one or more embodiments, the diffusion region further includes dopant atoms diffused within an uppermost portion of the substrate located below the source/drain region.

According to one or more embodiments, the source/drain region includes a T-shaped epitaxial layer.

According to one or more embodiments, each of the plurality of channel layer includes a dumbbell-like shape.

According to one or more embodiments, the semiconductor structure further includes a source/drain contact in contact with an uppermost surface of the source/drain region, the source/drain contact being separated from the metal gate stack by the sidewall gate spacer, and a portion of the substrate below the plurality of channel layers being located between shallow trench isolation regions.

According to one or more embodiments, the plurality of channel layers includes at least one of a nanosheet, a nanowire, and a nano-ellipse.

The method as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Spatially relative terms, such as “inner,” “outer,” “beneath,” “below,” “lower,” “above,” “upper,” “top,” “bottom,” and the like, may be used herein for case of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” may encompass both an orientation of above and below. The device may be otherwise oriented (rotated 90 degrees or at other orientations) and the spatially relative descriptors used herein interpreted accordingly.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a first gate-all-around device disposed on a first region of a substrate, the first gate-all-around device comprising a first metal gate stack surrounding a first channel layer, the first metal gate stack being separated from a first source/drain region by a dielectric inner spacer disposed on opposite sides of the first metal gate stack; and
a second gate-all-around device disposed on a second region of the substrate, the second gate-all-around device comprising a second metal gate stack surrounding a second channel layer, the second metal gate stack being separated from a second source/drain region by an epitaxial layer disposed on opposite sides of the second metal gate stack.

2. The semiconductor structure of claim 1, wherein the first gate-all-around device is an n-FET device, and the second gate-all-around device is a p-FET device.

3. The semiconductor structure of claim 1, wherein each of the first metal gate stack and the second metal gate stack further comprises a gate dielectric material.

4. The semiconductor structure of claim 1, wherein the second gate-all-around device further comprises:
a second sidewall gate spacer located along opposite sidewalls of a portion of the second metal gate stack disposed above the second channel layer, wherein a thickness of the second sidewall gate spacer defines an extension region for the second gate-all-around device; and
a diffusion region located within the extension region, the diffusion region including an outer portion of the second channel layer and an outer portion of the epitaxial layer.

5. The semiconductor structure of claim 4, wherein the diffusion region is located at an interface between the second source/drain region, the second channel layer and the epitaxial layer, the diffusion region having a U-shaped perimeter that surrounds the second source/drain region, the diffusion region including diffused dopant atoms from the second source/drain region.

6. The semiconductor structure of claim 1, wherein the second source/drain region and the epitaxial layer generate at least one of a compressive strain and a tensile strain on the second channel layer depending on a type of material selected to form the second source/drain region and the epitaxial layer.

7. The semiconductor structure of claim 1, wherein a material forming the epitaxial layer comprises at least one of Silicon and Silicon doped with Boron, and a material forming the second source/drain region comprises Silicon-Germanium doped with Boron.

8. A semiconductor structure, comprising:
a plurality of channel layers vertically stacked over a substrate;
a metal gate stack including a gate dielectric material, the metal gate stack being located between the plurality of channel layers;
an epitaxial layer disposed on opposite sides of the metal gate stack;
a source/drain region adjacent to the plurality of channel layers and the epitaxial layer; and
a diffusion region located at an interface between the source/drain region, the plurality of channel layers and the epitaxial layer, the diffusion region having a U-shaped perimeter that surrounds the source/drain region, the diffusion region including diffused dopant atoms from the source/drain region.

9. The semiconductor structure of claim 1, wherein the metal gate stack surrounds the plurality of channel layers and is separated from the source/drain region by the epitaxial layer.

10. The semiconductor structure of claim 1, wherein the source/drain region adjacent to the plurality of channel layers and the epitaxial layer generate at least one of a compressive strain and a tensile strain on the plurality of channel layers depending on a type of material selected to form the source/drain region and the epitaxial layer.

11. The semiconductor structure of claim 1, wherein the semiconductor structure is a P-type transistor with the epitaxial layer comprising at least one of Silicon and Silicon doped with Boron, and the source/drain region comprising Silicon-Germanium doped with Boron.

12. The semiconductor structure of claim 1, further comprising:
a sidewall gate spacer located along opposite sidewalls of a portion of the metal gate stack disposed above an uppermost channel layer of the plurality of channel layers.

13. The semiconductor structure of claim 12, wherein a portion of the epitaxial layer is located on opposite sides of each of the plurality of channel layers, the portion of the epitaxial layer extending outwards from the sidewall gate spacer.

14. The semiconductor structure of claim 12, wherein outer sidewalls of the epitaxial layer are vertically aligned with outer sidewalls of the plurality of channel layers and outer sidewalls of the sidewall gate spacer.

15. The semiconductor structure of claim 8, wherein the diffusion region further comprises dopant atoms diffused within an outer portion of each of the plurality of channel layers and within an outer portion of the epitaxial layer.

16. The semiconductor structure of claim 8, wherein the diffusion region further comprises dopant atoms diffused within an uppermost portion of the substrate located below the source/drain region.

17. The semiconductor structure of claim 8, wherein the source/drain region comprises a T-shaped epitaxial layer.

18. The semiconductor structure of claim 8, wherein each of the plurality of channel layer includes a dumbbell-like shape.

19. The semiconductor structure of claim 12, further comprising:
a source/drain contact in contact with an uppermost surface of the source/drain region, the source/drain contact being separated from the metal gate stack by the sidewall gate spacer, and
a portion of the substrate below the plurality of channel layers being located between shallow trench isolation regions.

20. The semiconductor structure of claim 8, wherein the plurality of channel layers comprises at least one of a nanosheet, a nanowire, and a nano-ellipse.
